(19) United States
(12) Patent Application Publication
(10) Pub. No.: US 2009/0039908 A1
(43) Pub. Date: Feb. 12, 2009

(54) MICROSTRUCTURE INSPECTING APPARATUS AND MICROSTRUCTURE INSPECTING METHOD

(75) Inventors: Naoki Ikeuchi, Tokyo (JP); Masami Yakabe, Tokyo (JP); Akiko Kamigori, Hyogo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/282,744

(22) PCT Filed: Apr. 12, 2006
(86) PCT No.: PCT/JP2007/058069

§ 371 Date: Sep. 12, 2008

(30) Foreign Application Priority Data
Apr. 26, 2006 (JP) 2006-122160

(51) Int. Cl. G01R 31/02

(52) U.S. Cl. 324/754

(57) ABSTRACT

A microstructure inspecting apparatus for evaluating a characteristic of at least one microstructure having a movable section formed on a substrate, includes: a probe, which electrically connects with pads formed on the microstructure, for obtaining an electric signal of the microstructure; a plurality of nozzles, positioned in the vicinity of the movable section of the microstructure, for discharging or sucking a gas; a nozzle flow rate controller for controlling a flow rate of the gas discharged from or sucked into the plurality of nozzles; and an evaluation unit for detecting a displacement of the movable section of the microstructure by using the electric signal obtained through the probe, wherein the displacement is made by the gas discharged from or sucked into the plurality of nozzles, and evaluating the characteristic of the microstructure based on the detected result.

### TECHNICAL FIELD

The present disclosure relates to an inspecting apparatus and an inspecting method for inspecting a microstructure such as MEMS (Micro Electro Mechanical Systems).

### BACKGROUND ART

Recently, MEMS devices, which integrated various mechanical, electronic, optical and chemical functions by using a microfabrication technology or the like, are attracting attention. As examples of MEMS technology that have been in practical use, there are sensors used in an automobile or a medical field, and the MEMS devices are mounted in microsensors such as an acceleration sensor, a pressure sensor, an air flow sensor or the like. Further, an application of the MEMS technology to an inkjet printer head has enabled an increase of the number of nozzles for jetting ink and an improvement of ink jetting accuracy, which in turn allows an enhancement of printing quality and speed. Further, a micro mirror array or the like used in a reflective type projector is also known as a general MEMS device.

It is expected that development of various sensors or actuators using the MEMS technology will expand application range of the MEMS devices to an optical communication/mobile device, a peripheral device of a calculator, a bio-analysis system, a mobile power source, and so forth.

Meanwhile, with the development of the MEMS devices, a method for properly inspecting the MEMS devices is also getting important especially because the MEMS devices are formed of microstructures. Conventionally, evaluation on device characteristics of the MEMS devices has been performed after packaging the MEMS devices, by way of rotating or vibrating the MEMS devices for every package. However, it is more desirable to detect defects of the devices by performing an appropriate inspection at an early stage such as in a wafer state after a microfabrication process, thereby raising the production yield while reducing the manufacturing costs.

Patent Document 1 discloses an inspecting method for determining characteristics of an acceleration sensor formed on a wafer by detecting a resistance value thereof, which is varied as a result of spraying air to the acceleration sensor.

Patent Document 1: Japanese Patent Laid-open Application No. H5-34371

### DISCLOSURE OF THE INVENTION

### Problems to be Solved by the Invention

When inspecting characteristics of a MEMS device having a microscopic movable section, a physical stimulus needs to be applied to the MEMS device from the exterior. In general, a structure having a microscopic movable section such as an acceleration sensor is a device whose response characteristic varies even for a microscopic movement. Accordingly, a highly accurate inspection is required to be performed to inspect the characteristics of the MEMS device. Further, an inspecting method without involving a contact with the movable section of the device is more desirable. One example of such non-contact type inspecting methods is disclosed in Patent Document 1.

In the technology disclosed in Patent Document 1, however, movements of a movable section cannot be precisely controlled because an area for jetting an air flow is larger than the movable section in a target chip to be inspected, or is not controlled. Moreover, when the rear surface of the movable section has the same height as a supporting structure, the movable section needs to be displaced upward. However, with the conventional method having only a function of discharging the air, it is impossible to displace the movable section in the upward direction of the wafer.

As a method for inspecting an acceleration sensor in a wafer state, there is proposed a method of detecting a movement of a movable section thereof by applying a sound wave to the movable section. However, in case of a sensor having low detection sensitivity, the application of the sound wave alone cannot generate a sufficient physical input amount (energy), so that an enough vibration of the movable section cannot be obtained, and a sufficient dynamic test may not be performed.

In view of the foregoing, the present disclosure provides an inspecting apparatus capable of performing a dynamic test of characteristics in each direction of degree of freedom with respect to a microstructure having the degree of freedom in multiple directions, without involving a direct contact with a movable section of the microstructure.

### Means for Solving the Problems

In accordance with a first aspect of the present invention, there is provided a microstructure inspecting apparatus for evaluating a characteristic of at least one microstructure having a movable section formed on a substrate, including: a probe, which electrically connects with an inspection electrode formed on the microstructure, for obtaining an electric signal of the microstructure; a plurality of nozzles, positioned in the vicinity of the movable section of the microstructure, for discharging or sucking a gas; a gas flow rate control unit for controlling a flow rate of the gas discharged from or sucked into the plurality of nozzles; and an evaluation unit for detecting a displacement of the movable section of the microstructure by using the electric signal obtained through the probe, wherein the displacement is made by the gas discharged from or sucked into the plurality of nozzles, and evaluating the characteristic of the microstructure based on the detected result.

It is desirable that the microstructure inspecting apparatus further includes a probe card, connected to the evaluation unit, including the probe and the plurality of nozzles.

Moreover, the microstructure inspecting apparatus further includes at least one sound wave generating unit for outputting a test sound wave to the movable section of the microstructure.

In addition, the microstructure inspecting apparatus further includes a conducting unit for electrically connecting the probe with the inspection electrode by using a fritting phenomenon.

The gas flow rate control unit may remove foreign substances adhered to the microstructure by controlling the flow rate of the gas discharged from or sucked into the plurality of nozzles.

The probe card further includes a foreign substance detecting unit for detecting foreign substances adhered to the microstructure, and if the foreign substances are detected by the foreign substance detecting unit, the gas flow rate control unit may remove the foreign substances adhered to the microstructure by controlling the flow rate of the gas discharged from or sucked into the plurality of nozzles.

The foreign substance detecting unit determines presence and location of the foreign substances by means of, for example, an image analyzing unit.

The microstructure is an acceleration sensor formed on the substrate.

Further, the microstructure is a device formed on a semiconductor wafer.

In accordance with a second aspect of the present invention, there is provided a microstructure inspecting method including: in order to obtain an electric signal of at least one microstructure having a movable section formed on a substrate, contacting a probe with a pad formed on the microstructure; positioning a plurality of nozzles for discharging or sucking a gas in the vicinity of the movable section of the microstructure, to displace the movable section of the microstructure; displacing the movable section of the microstructure by discharging or sucking the gas from the plurality of nozzles; detecting a displacement of the movable section of the microstructure by using the electric signal obtained through the probe, wherein the displacement is made by the gas discharged from or sucked into the plurality of nozzles; and evaluating a characteristic of the microstructure based on the displacement of the movable section detected by the electric signal.

### EFFECT OF THE INVENTION

In the microstructure inspecting apparatus and method in accordance with the present invention, flow rates of gases discharged or sucked by the plurality of nozzles can be controlled individually, so that it is possible to apply a displacement to a part of a movable section in a receding direction from the nozzles, while applying a displacement to another part of the movable section in an approaching direction toward the nozzles. As a result, characteristics of the microstructure can be inspected by varying displacement directions of the movable section, without having to bring the inspecting apparatus into a direct contact with the movable section of the microstructure.

### BRIEF DESCRIPTION OF THE DRAWINGS

FIG. 1 provides a schematic configuration view of a microstructure inspecting apparatus in accordance with an embodiment of the present invention;

FIG. 2 sets forth a block diagram to illustrate a configuration of an inspection control unit and a prober unit of a resistance measurement system of FIG. 1;

FIG. 3 presents a top view of a triple-axis acceleration sensor;

FIG. 4 is schematic configuration view of the triple-axis acceleration sensor;

FIG. 5 illustrates strains of weight body and beams when an acceleration is applied in each axial direction;

FIGS. 6A and 6B are circuit diagrams of Wheatstone bridges installed on each axis;

FIGS. 7A to 7C describe output response characteristics with respect to inclination angles of the triple-axis acceleration sensor;

FIG. 8 describes a relationship between an acceleration of gravity (input) and a sensor output;

FIG. 9 presents a schematic view to illustrate a configuration of nozzles and a wafer in accordance with the embodiment of the present invention;

FIGS. 10A and 10B set forth schematic views to illustrate an example of a combination of discharging or sucking directions of the nozzles and a displacement direction of a movable section;

FIGS. 11A and 11B depict schematic views to illustrate an example of a displacement direction of the movable section when air is discharged from four nozzles;

FIGS. 12A and 12B present schematic views to illustrate an example of a displacement direction of the movable section when air is discharged from one nozzle;

FIGS. 13A and 13B show schematic views to illustrate an example of a displacement direction of the movable section when air is discharged from two nozzles;

FIGS. 14A and 14B offer schematic views to illustrate an example of a displacement direction of the movable section when air is sucked into four nozzles;

FIGS. 15A and 15B present schematic views to illustrate an example of a displacement direction of the movable section when air is sucked into one nozzle;

FIGS. 16A and 16B provide schematic views to illustrate an example of a displacement direction of the movable section when air is sucked into two nozzles;

FIGS. 17A and 17B depict schematic views to illustrate an example of a combination of discharging or sucking directions of the nozzles and a displacement direction of a movable section;

FIG. 18 is flowchart to describe an operation example of the inspecting apparatus in accordance with the embodiment of the present invention;

FIG. 19 illustrates an another configuration of probes and nozzles;

FIG. 20 illustrates a configuration of a probe card in accordance with a second modification example of the embodiment of the present invention;

FIG. 21 presents a flowchart to describe an operation example of detecting and removing foreign substances by the inspecting apparatus in accordance with a third modification example of the embodiment of the present invention;

FIG. 22 illustrates a configuration of a probe card in accordance with the third modification example of the embodiment of the present invention; and

FIG. 23 depicts a block diagram to illustrate a configuration of an inspection control unit and a prober unit of a resistance measurement system in accordance with the third modification example of the embodiment of the present invention.

### EXPLANATION OF CODES

1 Inspecting apparatus
2 Inspection control unit
3 Nozzle flow rate controller (Gas flow rate control means)
4 Probe card
4a Probes
4b Opening area
5 Fritting circuit
6 Characteristic evaluation unit (Evaluating means)
7 Switching unit
8 Wafer (Substrate)
8a Electrode pads (Pads)
9 Speaker (Sound wave generating means)
10 Nozzles
13 Probe controller
15 Prober unit
16 Acceleration sensor (Microstructure)
16a Movable sections
20 Internal bus
21 Controller
22 Main storage unit
23 External storage unit
24 Input unit
25 Input/output unit
26 Display unit (Display means)
70 Vibration-proof material
81 Camera (Foreign substance detecting means)
83 Supporting unit
85 Camera control unit
87 Image analysis unit (Image analyzing means)
AR Weight bodies (Movable sections)
BM Beams (Movable sections)
TP Chip (Microstructure)

### BEST MODE FOR CARRYING OUT THE INVENTION

Hereinafter, embodiments of the present invention will be described in detail with reference to the accompanying drawings. In the accompanying drawings, like reference numerals designate like parts or corresponding parts, and a description thereof will be omitted.

### FIRST EMBODIMENT

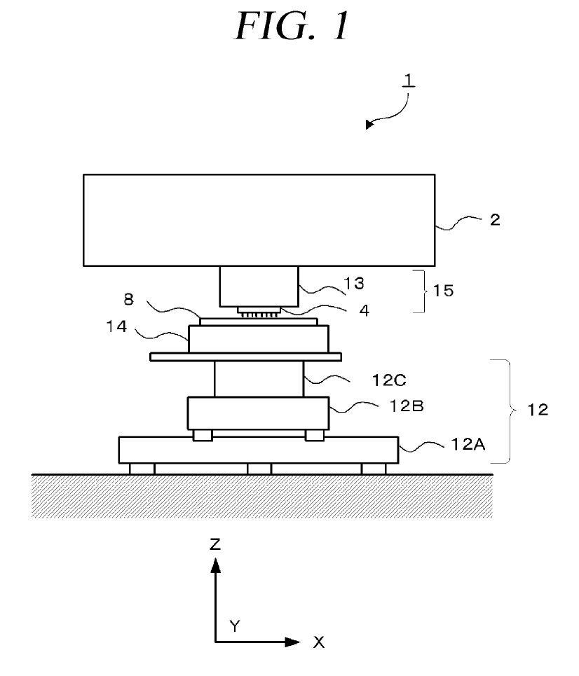

FIG. 1 provides a schematic configuration view of an inspecting apparatus 1 in accordance with an embodiment of the present invention. As shown in FIG. 1, the inspecting apparatus 1 includes a loader unit 12 for transferring a test target object, for example, a wafer 8; a prober unit 15 for performing an inspection of electrical characteristics of the wafer 8; and an inspection control unit 2 for measuring characteristic values of an acceleration sensor, which is provided on the wafer 8, by the prober unit 15.

The loader unit 12 includes a mounting member (not shown) for mounting thereon a cassette accommodating, e.g., twenty five sheets of wafers 8; and a wafer transfer mechanism for transferring the wafers 8 from the cassette of the mounting member sheet-by-sheet.

The wafer transfer mechanism has a main chuck 14 moving along three axial directions (i.e., X-, Y- and Z-axis directions) by X, Y and Z tables 12B, 12A and 12C which function as moving mechanisms in three orthogonal axes of X, Y and Z, respectively. The main chuck 14 is provided to rotate the wafer 8 around the Z axis. To elaborate, the wafer transfer mechanism includes the Y table 12A moving along the Y direction, the X table 12B moving on the Y table 12A along the X direction; and the Z table 12C moving up and down along the Z direction, wherein the Z table 12C is disposed such that its axial center is aligned to be coincident with the center of the X table 12B. The main chuck 14 is moved in the X, Y and Z directions by the X table 12B, the Y table 12A and the Z table 12C, respectively. Further, the main chuck 14 is also rotated in forward and backward directions within a predetermined range by a rotation driving mechanism rotating around the Z axis.

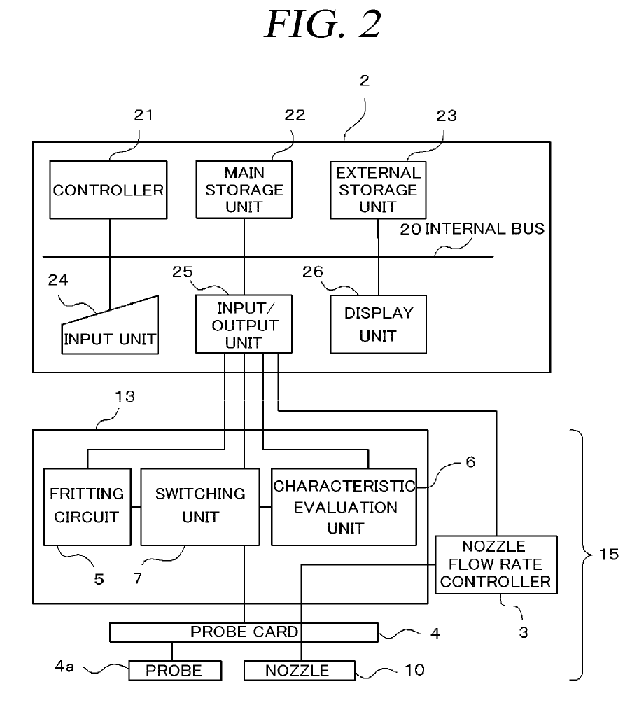

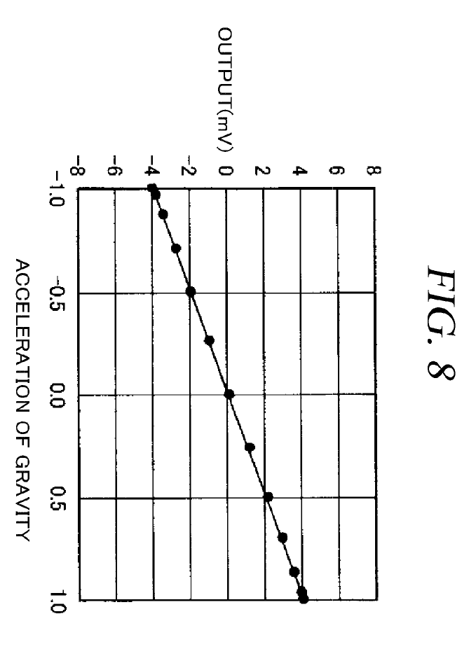

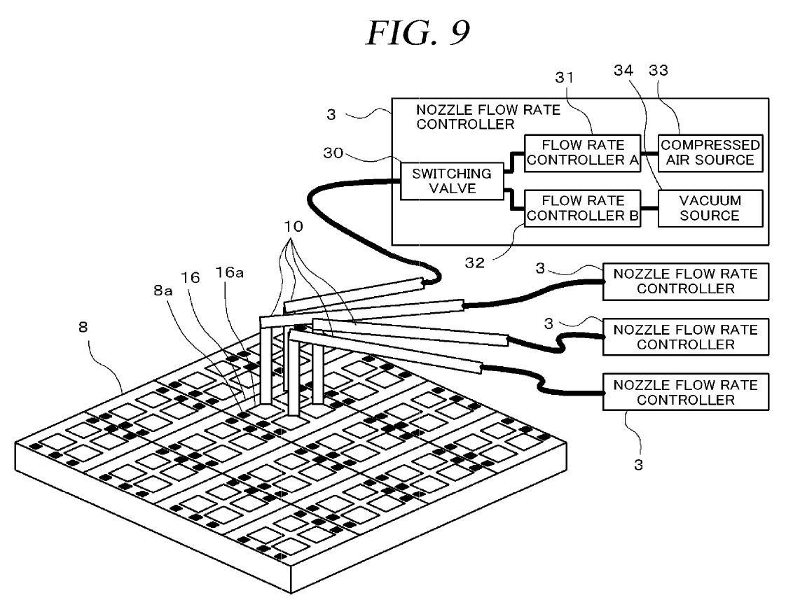

The prober unit 15 includes a probe card 4 and a probe controller 13 for controlling the probe card 4. The probe card 4 includes testing probes 4a which are brought into contact with electrode pads 8a (see FIG. 9) formed on the wafer 8 and made of a conductive metal such as copper, a copper alloy, aluminum or the like. When the probes 4a and the electrode pads 8a come into contact with each other, a contact resistance therebetween is reduced by a fritting phenomenon, so that they are allowed to be electrically connected with each other. Further, the prober unit 15 includes a plurality of nozzles 10 (see FIG. 2) for discharging or sucking a gas to or from movable sections 16a of an acceleration sensor 16 (see FIG. 9) formed on the wafer 8. The probe controller 13 controls the probes 4a of the probe card 4 and nozzle flow rate controllers connected to the nozzles 10, and applies a displacement to the acceleration sensor 16 and then detects movements of the movable sections 16a of the acceleration sensor 16 as electric signals through the probes.

The prober unit 15 includes an alignment mechanism (not shown) for carrying out alignment of the probes 4a of the probe card 4 to the wafer 8. The nozzles 10 (see FIG. 9) of the prober unit 15 are arranged such that their front ends face the movable sections 16a of the acceleration sensor 16 of the wafer 9, and by discharging or sucking a gas through the nozzles 10, the prober unit 15 forces the movable sections 16a to make a displacement. Further, the prober unit 15 also measures characteristic values of the acceleration sensor 16 formed on the wafer 8 by allowing the probes 4a of the probe card 4 and the electrode pads 8a on the wafer 8 to come into electrical contact with each other.

FIG. 2 is a block diagram illustrating configurations of the inspection control unit 2 and the prober unit 15 of the inspecting apparatus 1. The inspection control unit 2 and the prober unit 15 constitute an acceleration sensor evaluation and measurement circuit.

As shown in FIG. 2, the inspection control unit 2 includes a controller 21, a main storage unit 22, an external storage unit 23, an input unit 24, an input/output unit 25 and a display unit 26. The main storage unit 22, the external storage unit 23, the input unit 24, the input/output unit 25 and the display unit 26 are all connected to the controller 21 via an internal bus 20.

The controller 21 includes a CPU (Central Processing Unit) or the like, and it performs a process for measuring characteristics of a sensor on the wafer 8, for example, a resistance value of a resistor, a current or a voltage of a circuit constituting the sensor, and the like according to a program stored in the external storage unit 23.

The main storage unit 22 includes a RAM (Random-Access Memory) or the like, and loads therein the program stored in the external storage unit 23 and is used as a working area of the controller 21.

The external storage unit 23 includes a nonvolatile memory such as a ROM (Read Only Memory), a flash memory, a hard disk, a DVD-RAM (Digital Versatile Disc Random-Access Memory), a DVD-RW (Digital Versatile Disc Rewritable), or the like, and pre-stores therein the program required to allow the desired process to be carried out by the controller 21. Further, in response to a command from the controller 21, the external storage unit 23 supplies data stored by the program to the controller 21, and also stores therein data sent from the controller 21.

The input unit 24 includes a keyboard, a pointing device such as a mouse, and an interface device for connecting the keyboard and the pointing device to the internal bus 20. The start of evaluation and measurement, the selection of a measurement method, or the like is inputted through the input unit 24 and is sent to the controller 21.

The input/output unit 25 includes a serial interface or a LAN (Local Area Network) interface connected to the probe controller 13 which is under the control of the inspection control unit 2. Through the input/output unit 25, instructions upon a contact of the probes 4a with the electrode pads 8a of the wafer 8; an electrical conduction therebetween; a switching operation thereof; a control of the gas flow rate discharged to or sucked from the movable sections 16a of the acceleration sensor 16; and the like are transmitted to the probe controller 13. Further, measured results are inputted thereto.

The display unit 26 has a CRT (Cathode Ray Tube), an LCD (Liquid Crystal Display), or the like, and displays thereon, for example, a frequency response characteristic which is a measured result.

The probe controller 13 includes nozzle flow rate controllers 3, a fritting circuit 5, a characteristic evaluator 6 and a switching unit 7. The characteristic evaluator 6 supplies the probe card 4 with a power for measuring an electric signal of the acceleration sensor 16, and measures a current flowing in the acceleration sensor 16, a voltage between terminals, and so forth.

The nozzle flow rate controllers 3 control the flow rate of the gas discharged from or sucked into the nozzles 10 to make a displacement to the movable sections 16a of the acceleration sensor 16 (see FIG. 9) formed on the wafer 8. Specifically, flow rates of gases discharged from or sucked into the plurality of nozzles 10 are controlled individually so that a displacement is made to the movable sections 16a of the acceleration sensor 16.

The fritting circuit 5 is a circuit which supplies electric currents to the probes 4a of the probe card 4 in contact with the electrode pads 8a of the wafer 8, and generates a fritting phenomenon between the probes 4a and the electrode pads 8a to thereby reduce the contact resistance therebetween.

The characteristic evaluator 6 measures and evaluates characteristics of a microstructure. For example, the characteristic evaluator 6 applies a static or dynamic displacement to the movable sections 16a and then measures a response of the acceleration sensor 16, and determines whether it is within a designed reference range.

The switching unit 7 performs a switching operation to connect each probe 4a of the probe card 4 to either one of the fritting circuit 5 and the characteristic evaluator 6.

Before explaining an inspecting method in accordance with an embodiment of the present invention, a triple-axis acceleration sensor 16 of a microstructure to be inspected will be described first.

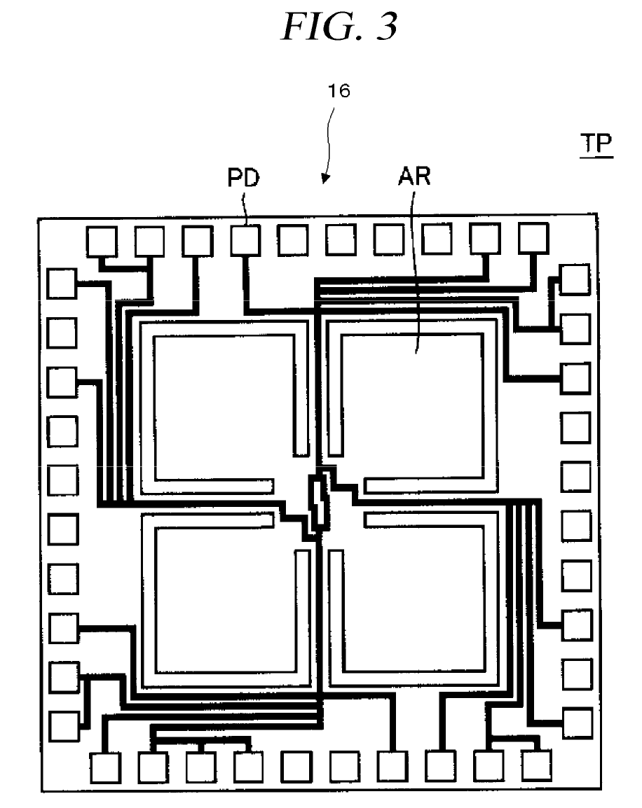

FIG. 3 illustrates a top view of the triple-axis acceleration sensor 16. As shown in FIG. 3, a multiplicity of electrode pads PD are disposed on the periphery of a chip TP formed on the wafer 8, and metal interconnections are also provided on the chip TP to transceive electric signals to and from the electrode pads PD. Further, on a central portion of the chip TP, there are arranged four weight bodies AR in a clover shape.

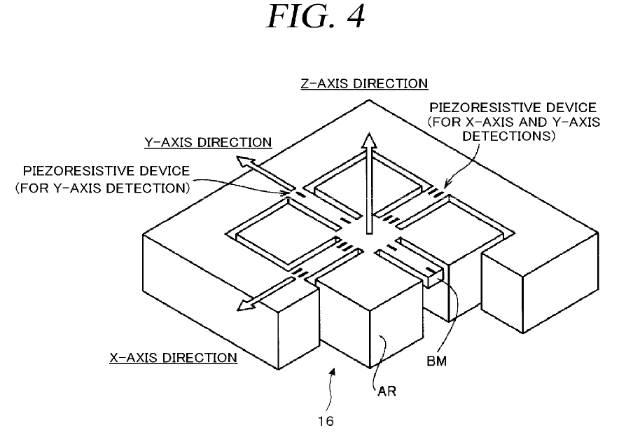

FIG. 4 presents a schematic view of the triple-axis acceleration sensor 16. The triple-axis acceleration sensor 16 is of a piezoresistive type in which piezoresistive devices serving as detecting elements are installed as diffusion resistors. The acceleration sensor 16 of the piezoresistive type can be fabricated through a low-cost IC process. Since the sensitivity of the acceleration sensor does not deteriorate even if the resistor devices, which serve as the detecting elements, are formed small, this type of acceleration sensor is advantageous for device miniaturization and cost reduction.

To elaborate the configuration of the acceleration sensor 16, a central portion of the weight body AR is supported by four beams BM. The beams BM are arranged to cross each other perpendicularly in two axial directions, i.e., X- and Y-axis directions, and four piezoresistive devices are provided along each axis. Further, four piezoresistive devices for Z-axis directional detection are disposed beside the piezoresistive devices for the X-axis directional detection. Top surfaces of the weight body AR form the clover shape, and they are connected to the beams BM at the central portion thereof. By adopting the clover-shaped structure, the size of the weight body AR and the length of the beams can be expanded, so that a compact high-sensitivity acceleration sensor 16 can be realized.

The operation principle of the piezoresistive type triple-axis acceleration sensor 16 is as follows. If a weight body AR is given an acceleration (force of inertia), the beams BM are strained, and the acceleration is detected based on a variation in resistance values of the piezoresistive devices formed on the surfaces of the beams BM. Sensor outputs are obtained from outputs of Wheatstone bridges independently disposed on each of the three axes.

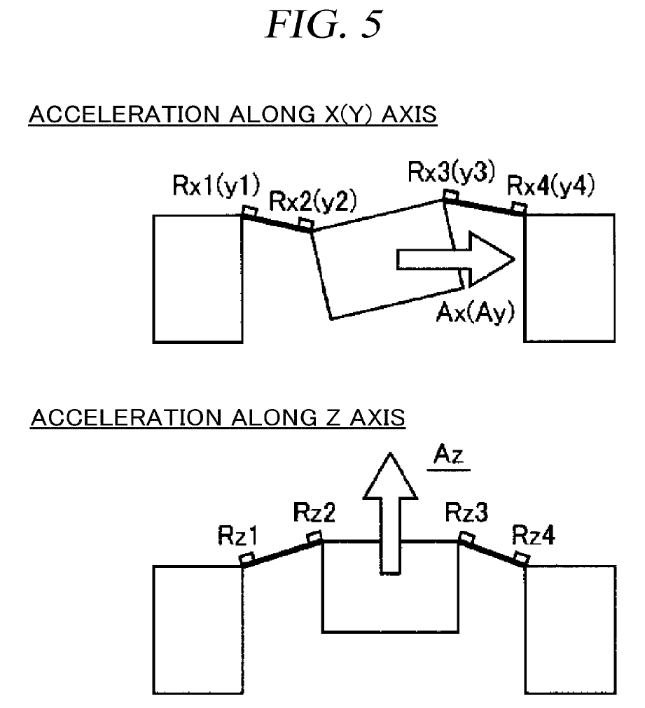

FIG. 5 presents a conceptual diagram to describe strain of the weight body and the beams when the acceleration is applied in each axial direction. As illustrated in FIG. 5, a piezoresistive device is characterized in that its resistance value is varied by a strain applied thereto (referred to as a piezoresistive effect). In case of an extension strain, the resistance value increases, while the resistance value decreases in case of a compression strain. In the present embodiment, X-axis directional detection piezoresistive devices (Rₓ1 to Rₓ4), Y-axis directional detection piezoresistive devices (R_{y}1 to R_{y}4) and Z-axis directional detection piezoresistive devices (R_{z}1 to R_{z}4) are provided for illustration.

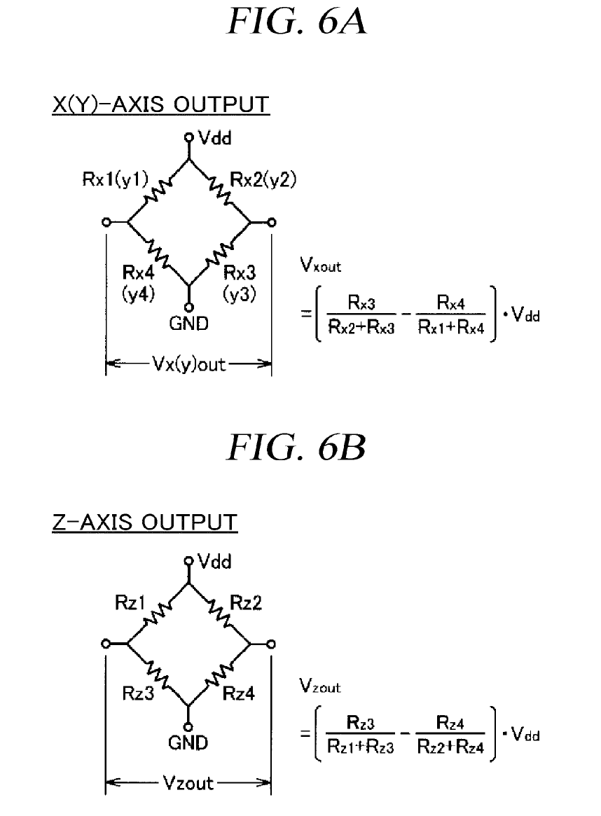

FIGS. 6A and 6B show circuit diagrams of Wheatstone bridges provided on the respective axes. FIG. 6A is a circuit diagram of the Wheatstone bridge on the X (Y) axis, while FIG. 6B is a circuit diagram of the Wheatstone bridge on the Z axis. Output voltages of the X and Y axes are set to be Vₓₒᵤₜ and V_{yout}, respectively, and an output voltage of the Z axis is set to be V_{zout}.

As described above, due to the inflicted strain, the resistance values of the four piezoresistive devices on each axis are varied. Based on these variations of each piezoresistive device, circuit outputs generated by the Wheatstone bridges on, for example, the X and Y axes, that is, acceleration components of the X and Y axes are detected as independently separated output voltages. Further, as the configuration of the above circuit, metal interconnections as shown in FIG. 3 or the like are connected, so that the output voltage for each axis is detected from the electrode pad 8a.

Further, since this triple-axis acceleration sensor 16 can detect a DC component of acceleration, it can also be utilized as an inclination angle sensor for detecting an acceleration of gravity. Though the embodiment of the present invention has been described with respect to the acceleration sensor 16, it can be applied to various types of devices having movable sections 16a. For example, the present invention can be applied to detecting a dynamic characteristic of, for example, a pressure sensor. Further, the present invention can also be used to detect characteristics of a thin-film type device, e.g., a strain gauge or the like by applying a displacement thereto.

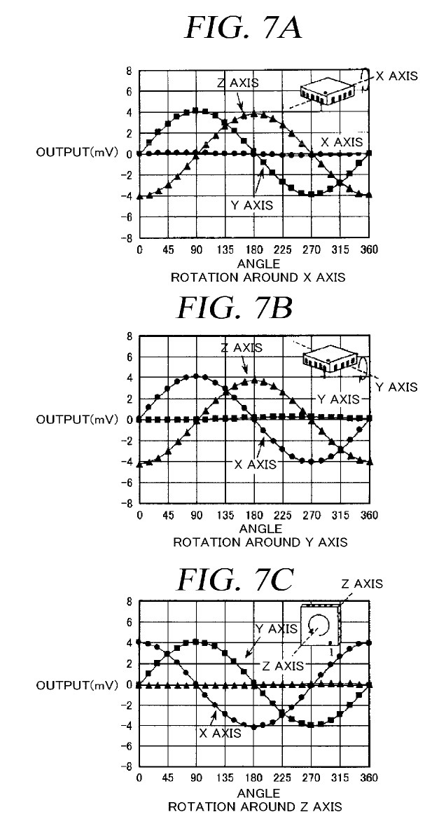

FIGS. 7A to 7C provide graphs to describe an output response of the triple-axis acceleration sensor 16 for every inclination angle. As shown in FIGS. 7A to 7C, the acceleration sensor 16 is rotated around the X, Y and Z axes and bridge outputs of each of the X, Y and Z axes are measured by a digital voltmeter. A low-voltage power supply of +5 V is used as a power source for the sensor. Each of measurement points in FIGS. 7A to 7C, is plotted by using a value obtained by arithmetically subtracting a zero point offset from each axis output.

FIG. 8 illustrates a relationship between an acceleration of gravity (input) and a sensor output. The input-output relationship in FIG. 8 is obtained by calculating a gravity acceleration component related to each of the X, Y and Z axes from a cosine of the inclination angle in FIGS. 7A to 7C; analyzing the relationship between the gravity acceleration (input) and the sensor output; and then evaluating the linearity of the input and output. That is, the acceleration and the output voltage are in a substantially linear relationship.

Referring to FIGS. 1 and 2, the microstructure inspecting method in accordance with the embodiment of the present invention is a method in which an airflow is blown to the triple-axis acceleration sensor 16, i.e., the microstructure being inspected, from the nozzles 10, and characteristics of the microstructure are evaluated by detecting movements of the movable sections 16a of the microstructure based on the airflow.

Now, an evaluation method for the acceleration sensor 16 in accordance with the embodiment of the present invention will be explained. FIG. 9 is a schematic view showing configurations of the nozzles 10 and the wafer 8. The wafer 8 is provided with the acceleration sensor 16 having the movable sections 16a, and the electrode pads 8a for reading electric signals of the acceleration sensor 16 are formed on the wafer 8.

The probe card 4 includes the plurality of probes 4a to be brought into contact with the electrode pads 8a (see FIG. 2). The prober unit 15 of the inspecting apparatus 1 includes the nozzle flow rate controllers 3 for generating an airflow toward the movable sections 16a of the acceleration sensor 16, and the nozzles 10 for discharging or sucking the airflow toward or from the movable sections 16a of the acceleration sensor 16 by being disposed near the movable sections 16a (see FIG. 9).

Typically, the electrode pads 8a used as inspection electrodes to be electrically connected to the probes 4a are formed at the peripheral region of the sensor. Here, the nozzles 10 can be configured to be located in a region surrounded by the probes 4a such that front ends of the nozzles 10 are disposed in the vicinity of the movable sections 16a (weight bodies) placed near the center of the sensor. Each movable section 16a can be a film in case that the weight bodies AR, the beams BM, or the sensor is made of a membrane (film) structure.

The nozzles 10, as air passage pipes, are connected to switching valves 30 of the nozzle flow rate controllers 3. The nozzle flow rate controller 3 includes a compressed air source 33 and a vacuum source 34. The compressed air source 33 and the vacuum source 34 are connected to the switching valve 30 via a flow rate controller A 31 and a flow rate controller B 32, respectively. The flow rate controller A 31 controls a flow rate of the air discharged from the nozzle 10. The flow rate controller B 32 controls a flow rate of the air sucked into the nozzle 10. The switching valve 30 performs a switching operation to connect either one of the compressed air source 33 and the vacuum source 34 to the nozzle 10. When the compressed air source 33 and the nozzle 10 are connected to each other by the switching valve 30, air is discharged from the nozzle 10, whereas, when the vacuum source 34 and the nozzle 10 are connected to each other by the switching valve 30, the air is sucked into the nozzle 10.

The plurality of nozzles 10 are connected to the different nozzle flow rate controllers 3. A switching between the discharge and the suction of the air and the flow rates of the discharged or sucked air are individually controlled for each of the nozzles 10. By combining the direction of discharge and suction of the air and the flow rates of the air, it is possible to displace the movable sections 16a of the acceleration sensor 16 in any direction within the degree of freedom thereof. The flow of the air discharged from or sucked into the nozzles 10 is not limited to be constant, but may be varied. For example, the discharge and suction of the air can be switched alternately for one nozzle 10. Further, it is also possible to move the movable sections 16a in a vibration mode by varying the flow rate of the discharged or sucked air in a pulsating manner.

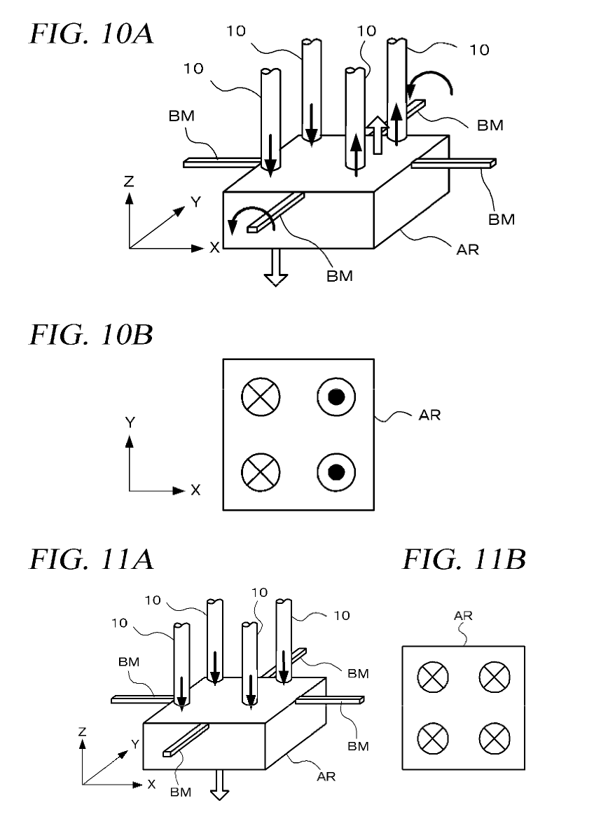

FIGS. 10A to 17B are schematic views for describing an example of combination of discharging or sucking directions of the nozzles 10, and displacement directions of the movable section 16a.

In FIGS. 10A to 17B, the weight body (AR) of the movable sections 16a is supported by the beams BM in X- and Y-axis directions. Four nozzles 10 are disposed to face the weight body (AR) arranged in the clover shape. In each figure, straight solid-lined arrows indicate directions of air discharged from or sucked into the nozzles 10; white arrows indicate forces applied to the weight body AR; and arc-shaped arrows indicate directions of twist applied to the beams BM. FIGS. 10A to 17B are diagrams viewed from a positive direction of the Z axis. In FIGS. 10A to 17B, a black circle surrounded by another circle indicates a flow of air oriented from the rear surface of the sheet toward the front surface thereof, while an X mark surrounded by a circle indicates a flow of air oriented from the front surface of the sheet toward the rear surface thereof.

FIGS. 10A and 10B illustrate a case in which air is sucked into two right nozzles 10 and discharged from the rest two left nozzles 10. The left-side of the weight body AR is displaced in a negative direction of the Z axis, while the right-side of the weight body AR is displaced in the positive direction of the Z axis. The beam BM of the Y-axis direction is twisted in a counterclockwise direction when viewed toward a positive direction of the Y axis.

FIGS. 11A and 11B illustrate a case in which air is discharged from the four nozzles 10. When the air is uniformly discharged from the four nozzles 10, the weight body AR is displaced in the negative direction of the Z axis as a whole. In such case, no twist is caused to the beams BM. If the flow rates of the air discharged from the four nozzles 10 are varied, the weight body AR is inclined and displaced in the negative direction of the Z axis as a whole.

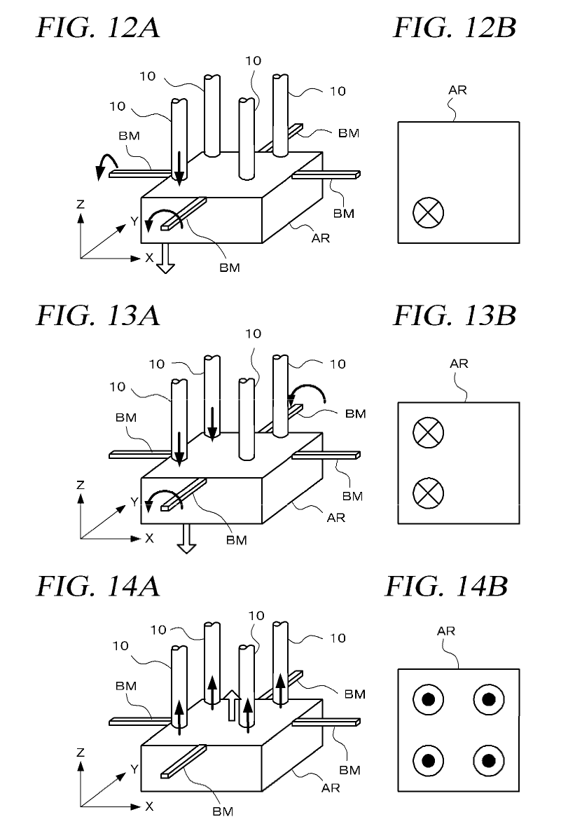

FIGS. 12A and 12B illustrate a case in which air is discharged from one nozzle 10, and no air flow is generated from the rest three nozzles 10. Though the weight body AR is displaced in the negative direction of the Z axis as a whole, a force applied to the weight body AR is unbalanced. Accordingly, the Y-axis directional beam BM is twisted in the counterclockwise direction when viewed toward the positive direction of the Y axis, and the X-axis directional beam BM is twisted in the clockwise direction when viewed toward the positive direction of the X axis.

FIGS. 13A and 13B illustrate a case in which air is discharged from two nozzles 10, and no air flow is generated in the other two nozzles 10. Though the weight body AR is displaced in the negative direction of the Z axis as a whole because the negative side of the X axis of the weight body AR is pushed toward the negative direction of the Z axis, the Y-axis directional beam BM is twisted in the counterclockwise direction when viewed toward the positive direction of the Y axis.

FIGS. 14A and 14B illustrate a case in which air is sucked into four nozzles 10. When the air is uniformly sucked into the four nozzles 10, the weight body AR is displaced in the Z-axis direction as a whole. In such case, the beam BM is not twisted. When the flow rate of the air sucked into the four nozzles 10 is varied, the weight body AR is inclined and displaced in the positive direction of the Z axis as a whole.

If the chip TP is inspected in the wafer 8 state when the bottom surface of the weight body AR is on the same plane as the bottom surface of the wafer 8, there may arise an occasion that the movable section 16a cannot be displaced toward a bottom surface direction of the wafer 8. In such case, it has been impossible to move the movable section 16a with the conventional method of performing an inspection through spraying air. However, the present method is capable of moving the movable section 16a by sucking air into the nozzles 10.

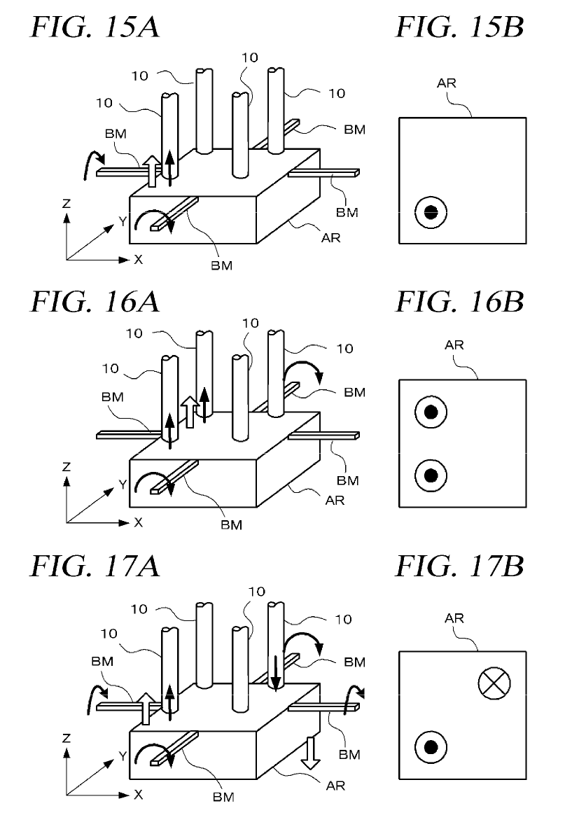

FIGS. 15A and 15B illustrate a case in which air is sucked into one nozzle 10, while no air flow is generated in the other three nozzles 10. Though the weight body AR is displaced in the positive direction of the Z axis as a whole, a force applied to the weight body AR is unbalanced, so that the beam BM of the Y axis direction is twisted in the clockwise direction when viewed toward the positive direction of the Y axis, while the beam BM of the X axis direction is twisted in the counterclockwise direction when viewed toward the positive direction of the X axis.

FIGS. 16A and 16B illustrate a case in which air is sucked into two nozzles 10, and no air flow is generated in the other two nozzles 10. Though the weight body AR is displaced in the positive direction of the Z axis as a whole because the negative side of the X axis of the weight body AR is sucked in the positive direction of the Z axis, the Y-axis directional beam BM is twisted in the clockwise direction when viewed toward the positive direction of the Y axis.

FIGS. 17A and 17B illustrate a case in which air is discharged from one of two nozzles 10 of the weight body AR while the other nozzle 10 positioned diagonally thereto sucks the air. In the case of FIGS. 17A and 17B, the Y-axis directional beam BM is twisted in the clockwise direction when viewed toward the positive direction of the Y axis, while the X-axis directional beam BM is twisted in the counterclockwise direction when viewed toward the positive direction of the X axis. If flow rates of discharged or sucked air are properly controlled, it is possible to change the strain direction without displacing the center of the weight body AR.

FIGS. 10A to 17B are some examples showing the combinations of discharging or sucking operations of the nozzles 10, and it should be noted that other various types of combinations are also possible. Further, as mentioned above, it is also possible to switch the direction of discharging or sucking air from the nozzles 10 or to vary the air flow rates. Moreover, the number of nozzles 10 corresponding to one movable section 16a is not limited to four. For example, the number of nozzles 10 can be two, three, five or more.

As described above, by the combinations of the direction of discharging or sucking air from or into the plurality of nozzles 10 with respect to the movable section 16a and the flow rate of the thus discharged or sucked air, the movable section 16a can be displaced in different directions. As a result, characteristics of each direction within the degree of freedom of the acceleration sensor 16 can be inspected by means of the inspecting apparatus 1.

In particular, when a piezoresistive device or the like is used in a microstructure having the movable section 16a, as in the MEMS device such as the acceleration sensor 16, a response characteristic varies depending on a pressure of the probes 4a. Accordingly, in order to perform a high-accuracy measurement as in the case of measuring a response characteristic of the sensor or the like, it is desirable to exclude the influence of external factors such as the probe pressure and the like.

For the electrical connection of the probes 4a and the electrode pads 8a, a fritting phenomenon is used to reduce the probe pressure while maintaining a contact resistance low. To use the fritting phenomenon, a pair of probes 4a is brought into contact with a single electrode pad 8a. After the pair of probes 4a and the electrode pad 8a come into contact with each other, the probe card 4 is connected to the fritting circuit 5, and an electric current is supplied to the probes 4a of the probe card 4 in contact with the electrode pad 8a of the wafer 8, and a fritting phenomenon is generated between the probes 4a and the electrode pad 8a, so that a contact resistance is reduced. Then, the switching unit 7 is switched to connect the probe card 4 to the characteristic evaluator 6.

As described above, the inspection control unit 2 of the inspecting apparatus 1 controls the probes 4a to be in contact with the electrode pads 8a of the wafer 8 by controlling the alignment mechanism of the prober unit 15. At the same time, the inspection control unit 2 locates the nozzles 10 in the vicinity of the movable section 16a of the acceleration sensor 16.

Subsequently, when an instruction is transmitted to the nozzle flow rate controller 3 so that air is discharged from or sucked into the nozzles 10, a displacement is made to the movable section 16a of the acceleration sensor 16 as a result of a flow of air. While applying the displacement to the movable section 16a of the acceleration sensor 16, electrical signals of the acceleration sensor 16 are detected by the probes 4a so that the characteristics of the acceleration sensor 16 are evaluated.

To evaluate the characteristics of the acceleration sensor 16, a response of the accelerator sensor 16 is measured, while controlling the direction and the amount of the displacement applied to the movable section 16a to be preset values. By measuring responses of the acceleration sensor 16 while varying the directions and the amounts of the displacement generated in the movable section 16a, a response characteristic of the acceleration sensor 16 can be evaluated. It is also possible to add a variation component to the displacement applied to the movable section 16a. Further, a pseudo white noise within a certain frequency range can be desirably used as the displacement applied to the movable section 16a. If the white noise is applied in a vibration manner, the response characteristic within the certain frequency range can be inspected without having to inspect the responses while varying an applied frequency.

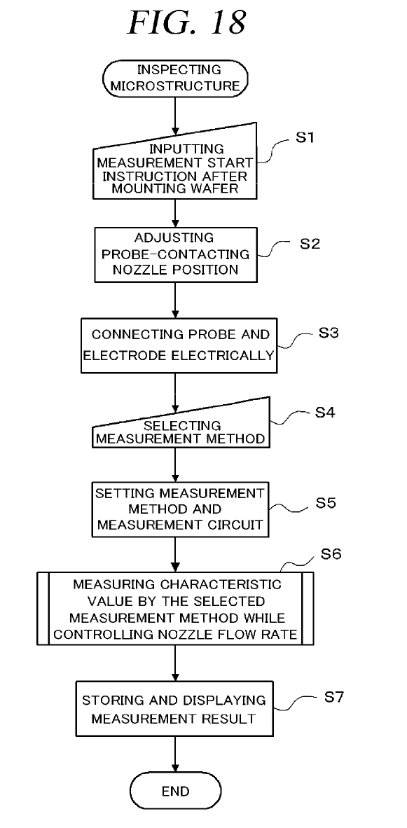

Now, a microstructure inspecting method in accordance with the first embodiment of the present invention will be described. FIG. 18 provides a flow chart to describe an example of an operation of the inspecting apparatus 1 in accordance with the embodiment of the present invention. The operation of the inspection control unit 2 is performed by the controller 21 working in cooperation with the main storage unit 22, the external storage unit 23, the input unit 24, the input/output unit 25 and the display unit 26.

The inspection control unit 2 first waits for a measurement start instruction to be inputted after the wafer 8 is loaded on the main chuck 14 (step S1). When the measurement start instruction is inputted to the controller 21 from the input unit 24, the controller 21 sends an instruction to the probe controller 13 via the input/output unit 25 to allow the probes 4a to come into contact with the electrode pads 8a of the wafer 8 (step S2). At the same time, the nozzles 10 are located at preset positions in the vicinity of the movable section 16a. Subsequently, an instruction is sent to the probe controller 13 to connect the probes 4a with the electrode pads 8a electrically by the fritting circuit 5 (step S3).

In the present embodiment, though the contact resistances between the electrode pads 8a and the probes 4a are reduced by the fritting phenomenon, other techniques (other than the fritting technology) can also be employed as a method for allowing the electrical connections while reducing the contact resistances. For example, there can be employed a method of transmitting ultrasonic waves to the probes 4a to partially destroy oxide films on the surfaces of the electrode pads 8a, thereby reducing the contact resistances between the electrode pads 8a and the probes 4a.

Thereafter, a selection of a measurement method is inputted (step S4). The measurement method may be stored in the external storage unit 23 in advance, or may be inputted from the input unit 24 for every measurement. When the measurement method is inputted, a measurement circuit used by the inputted measurement method, and a direction and an amount (and a frequency, and the like) of a displacement to be applied to the movable section 16a are set (step S5).

The measurement methods to be selected are related to, for example, an independent parallel displacement, an independent twist displacement, a combination displacement, a combination displacement of twist and the like in each direction within the degree of freedom of the acceleration sensor 16. Further, the methods also include a frequency sweeping inspection (frequency scan) for inspecting a response at each frequency by successively varying the frequency of the displacement, a white noise inspection for inspecting a response by applying a pseudo white noise within a preset frequency range, a linearity inspection for inspecting a response by varying an amplitude of the displacement while fixing the frequency of the displacement at a certain value, and so forth.

Then, by employing the selected measurement method, an electric signal, i.e., a response of the acceleration sensor 16 is detected from the probes 4a while displacing the movable section 16a of the acceleration sensor 16 by controlling the nozzle flow rate controller 3, so that a response characteristic of the acceleration sensor 16 is inspected (step S6). Then, a detected measurement result is stored in the external storage unit 23 and displayed on the display unit 26 (step S7).

Since the movable section 16a of the acceleration sensor 16 is displaced by a flow of a gas discharged from or sucked into the plural nozzles 10 disposed in the vicinity of the acceleration sensor 16, it is possible to perform the inspection with respect to the sensor having the multi-degrees of freedom, for every degree of freedom or for combined directions within the degrees of freedom. Further, in comparison with the method of inspecting the displacement of the movable section 16a by spraying air, it is possible to apply a displacement in the direction of sucking the movable section 16a. Thus, even when there is a limit in displacement direction of the movable section 16a in the wafer 8 state, the inspection can be carried out on the wafer 8.

### MODIFICATION EXAMPLE OF THE FIRST EMBODIMENT

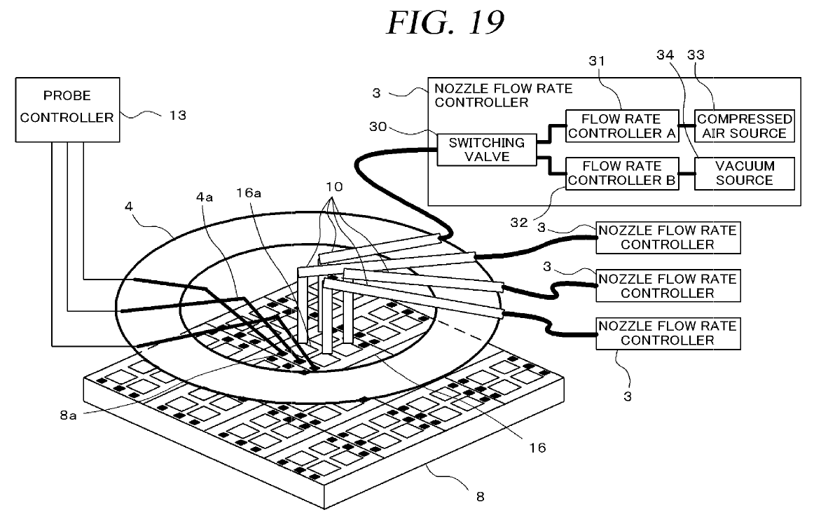

FIG. 19 illustrates another configuration example of probes 4a and nozzles 10. In the example of FIG. 19, a plurality of nozzles 10 is installed at a probe card 4. The arrangement of the probes 4a and the nozzles 10 is adjusted in advance. By positioning the probes 4a to come into contact with electrode pads 8a, the nozzles 10 are concurrently located at certain positions with respect to movable sections 16a. That is, it is not necessary to perform the position alignment of the nozzles 10 independently of the probes 4a. As a result, characteristics of the microstructure can be inspected by applying a displacement by the plurality of nozzles 10 while using a positioning mechanism of a conventional inspecting apparatus.

### MODIFICATION EXAMPLE 2 OF THE FIRST EMBODIMENT

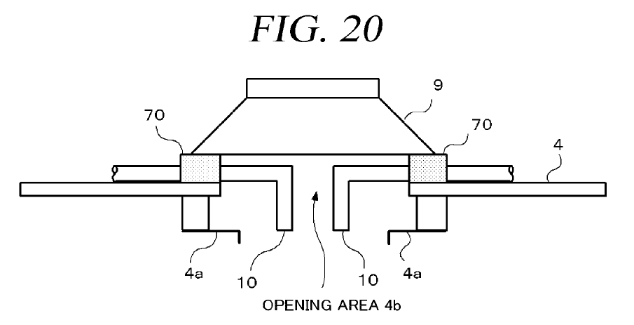

FIG. 20 illustrates a configuration of a probe card in accordance with a second modification example of the first embodiment of the present invention.

A probe card 4 shown in FIG. 20 further includes a speaker 9 for outputting a test sound wave in addition to the configuration of the probe card 4 in the first modification example. The test sound wave outputted by the speaker 9 is applied to the movable section 16a through an opening area 4b. The test sound wave makes a microstructure, for example, the movable section 16a of the acceleration sensor 16 to be vibrated. A frequency characteristic of the acceleration sensor 16 can be inspected by detecting signals of the acceleration sensor 16 while vibrating it with the test sound wave.

By varying an air flow of the nozzles 10, it is possible to inspect a frequency characteristic within a certain range. By combining the air flow with the test sound wave of the speaker 9, the frequency characteristic can be inspected successively from a constant displacement (DC component) to a high frequency. Alternatively, it is also possible to perform a complex inspection of, for example, inspecting a variation of the frequency characteristic by applying a vibration by the test sound wave of the speaker 9, while applying a constant displacement by the air flow of the nozzles 10.

The speaker 9 is supported against the probe card 4 by a supporting member. The supporting member may be made of a vibration-proof material (vibration-proof member) 70. The nozzles 10 are inserted through the vibration-proof material 70. By supporting the speaker 9 with the vibration-proof material 70, a vibration from the speaker 9 is prevented from reaching the probe card 4, so that a high-accuracy inspection can be carried out. The vibration-proof material 70 can be silicon rubber, resin, or the like.

Further, it is also desirable to install a microphone (not shown) at the vicinity of, for example, the opening area 4b and to detect the test sound wave applied from the speaker 9 to the acceleration sensor 16. The test sound wave outputted from the speaker 9 is controlled so that a sound signal detected by the microphone has a specific frequency characteristic. As a result, a test sound wave having the specific frequency characteristic can be applied to the movable section 16a.

### MODIFICATION EXAMPLE 3 OF THE FIRST EMBODIMENT

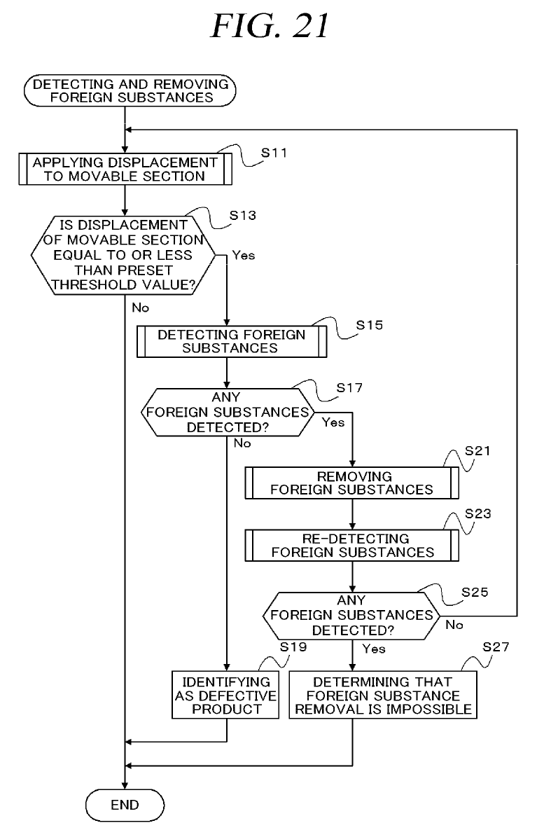

FIG. 21 provides a flowchart to describe an example of an operation of the inspecting apparatus 1 in accordance with the third modification example of the first embodiment of the present invention. The operation is a process of blowing out or sucking foreign substances, such as dust or contaminants, adhered to the acceleration sensor 16 by a gas discharged from or sucked into nozzles 10.

The operation disclosed in this flowchart is performed whenever necessary during the microstructure inspection process described in the flowchart of FIG. 18 (mainly, in the step S6).

When the foreign substances are adhered to the acceleration sensor 16, the movable section 16a may hardly or never move. In such case, two possibilities are taken into account: one is a case that the sensor is originally a defective product and the other is a case that the vicinity of the movable section 16a is clogged with the foreign substances. In the following, an acceleration sensor 16 corresponding to the former case is referred to as an originally defective product, and the sensor corresponding to the latter case is referred to as a seemingly defective product.

In an inspection employing a determination criterion in which, when a movable section 16a hardly or never moves, an acceleration sensor 16 having that movable section 16a is immediately determined as a defective product, a seemingly defective product is treated as a defective product without being distinguished from an originally defective product.

Meanwhile, the inspecting apparatus 1 in accordance with the embodiment of the present invention includes the nozzles 10, and the gas is discharged or sucked through the nozzles 10. As described above, the discharge or suction of gas is performed to apply a displacement to the movable section 16a. However, it is also possible to use such gas discharging or sucking mechanism for the purpose of removing foreign substances adhered to the acceleration sensor 16.

That is, the inspecting apparatus 1 in accordance with the embodiment of the present invention can perform a kind of cleaning operation for removing the foreign substances of the acceleration sensor 16 in addition to the above-described inspecting operation. Thus, when there is a seemingly defective product in which the vicinity of the movable section 16a is clogged with removable foreign substances, for example, the foreign substances can be eliminated by the cleaning operation, so that the seemingly defective product can be prevented from being treated as a real defective product. That is to say, in accordance with this modification example, at least a part of seemingly defective products is expected to be prevented from being treated as real defective products, which have not been distinguished from original defective products by the conventional technique. Accordingly, in accordance with this modification example, an increase of production yield of acceleration sensors 16 is expected.

So far, the description has been provided for the case that the movable section 16a hardly or never moves. To speak more precisely, it means that despite that a flow of gas is generated by the nozzles 10 to apply a displacement to the movable section 16a (step S11 of FIG. 21), a displacement of as high a degree as expected from the intensity of the gas flow does not occur. To be more specific, since there is defined a minimum value for displacement to be generated by the gas flow of the certain intensity, an evaluation is carried out upon the displacement by setting the minimum value as a threshold value (step S13). If a generated displacement is not greater than the threshold value, the acceleration sensor 16 is treated as a defective product in principle (Yes in the step S13 or No in step S17). Meanwhile, if the displacement degree exceeds the threshold value (No in the step S13), the acceleration sensor 16 is not regarded as a defective product at least in the present operation.

The inventive feature of the present modification example resides in an operation performed after the displacement degree of the movable section 16a is determined to be equal to or less than the threshold value in the step S13 (Yes in the step S13), and the operation is performed in a sequence as follows. That is, in accordance with the present modification example, the inspection control unit 2 generates a gas flow of certain intensity around the movable section 16a for a test (step S11). Then, the inspection control unit 2 determines whether a displacement corresponding to the intensity of the gas flow is generated in the movable section 16a through the probes 4a (step S13). Here, a predetermined threshold value is used as a determination criterion. When it is determined that the displacement degree is greater than the threshold value (No in the step S13), the process is completed without determining the acceleration sensor 16 being inspected as a defective product within the operation range for detecting and removing the foreign substances as shown in the flow chart of FIG. 21.

Meanwhile, when the displacement degree of the movable section 16a is determined to be equal to or less than the threshold value (Yes in the step S13), the inspection control unit 2 does not immediately determine the acceleration sensor 16 as a defective product, but considers a probability that foreign substances are adhered to the sensor. Specifically, the inspection control unit 2 attempts to detect the foreign substances by using, for example, a camera 81, a camera control unit 85 and an image analysis unit 87 to be described later (step S15).

The inspection control unit 2 determines whether the foreign substances are detected (step S17). If it is determined that no foreign substance is detected (No in the step S17), the inspection control unit 2 decides that the acceleration sensor 16 being inspected is an originally defective product (step S19), and the process is completed.

Meanwhile, when it is determined that the foreign substances are detected (Yes in the step S17), the inspection control unit 2 attempts to remove the foreign substances (step S21). Specifically, the inspection control unit 2 generates a flow of gas through the nozzles 10 based on an analysis result of the image analysis unit 87 to be described later, and attempts to blow out or suck the foreign substances by the gas flow.

Particularly, the inspection apparatus 1 in accordance with the embodiment of the present invention includes a plurality of nozzles. Accordingly, after finding out a position of the foreign substances through the image analysis, removal of the foreign substances can be attempted by generating a flow of gas on that position intensively or in many different directions. Thus, in comparison with a case of merely blowing a gas to the acceleration sensor 16 unfocusedly, the efficiency of removing the foreign substances improves.

The inspection control unit 2 then performs a detection of foreign substances (step S23). This process is substantially equivalent to a re-execution of the step S15. Then, the inspection control unit 2 determines whether the foreign substances are detected as a result of such re-execution (step S25). This determination process is identical to that of the step S17.

If it is determined that the foreign substances are still detected (Yes in the step S25), it implies that the foreign substances cannot be removed by the gas flow generated by the nozzles 10. Accordingly, the inspection control unit 2 decides that the removal of foreign substances in the acceleration sensor 16 being inspected is impossible (step S27), and the process is completed.

As for the acceleration sensor of which the foreign substances are found to be irremovable in the step S27, it is not concluded whether it is an originally defective product or a seemingly defective product because it is the one having the foreign substances adhered thereto but the foreign substances are irremovable. In such sense, the acceleration sensor 16 may be said to be in a kind of pending state. Accordingly, the conclusion in the step S27 needs to be distinguished from the conclusion in the step S19 which treats the acceleration sensor 16 as an originally defective product. For example, by storing a record in the external storage unit 23, there can be left a room for further attempt to remove the foreign substances by another method for the acceleration sensor 16 in the pending state.

Meanwhile, when it is determined that no foreign substance is detected (No in the step S25), the process returns to the step S11, and it is re-attempted to apply a displacement to the movable section 16a. Thereafter, it is determined again in the step S13 whether the displacement degree is sufficient or not. If the displacement degree is determined to be sufficient (No in the step S13), the process is completed, which implies that the foreign substances are actually removed by the foreign substance removal process (the step S21) and the acceleration sensor 16 is resultantly allowed to be normally operable. That is, it means that the sensor was the seemingly defective product at first. Meanwhile, if it is determined that the displacement degree is insufficient (Yes in the step S13), the foreign substance detection and determination process (the steps S15 and S17) are performed for the third time. However, since it is already determined in the step S25 that no foreign substance is detected, it would be determined that no foreign substance is detected (No in the step S17) except for a special case in which new foreign substances are adhered to the acceleration sensor 16 during a very short period of time when the steps from S25 to S17 are performed. Then, it is determined that the acceleration sensor 16 is an originally defective product (step S19), and the process is completed.

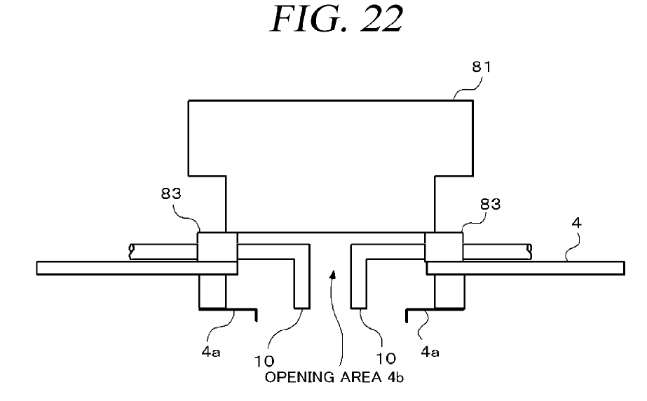

FIG. 22 schematically describes an installation method of the camera 81 for monitoring the adhesion of foreign substances to the acceleration sensor 16. This configuration is obtained by substituting the speaker 9 of FIG. 20 with the camera 81, wherein the camera 81 is installed on a probe card 4 via a supporting unit 83.

Further, FIG. 22 is just a schematic view, and a main body of the camera 81 need not be installed as shown in the figure in practice as long as the acceleration sensor 16 can be observed through an opening area 4b. It may be, for example, a fiberscope that is actually connected to the supporting unit 83. Further, it may be possible to set up a configuration for observing the entire part of the wafer 8 by the camera 81 independently of the probe card 4.

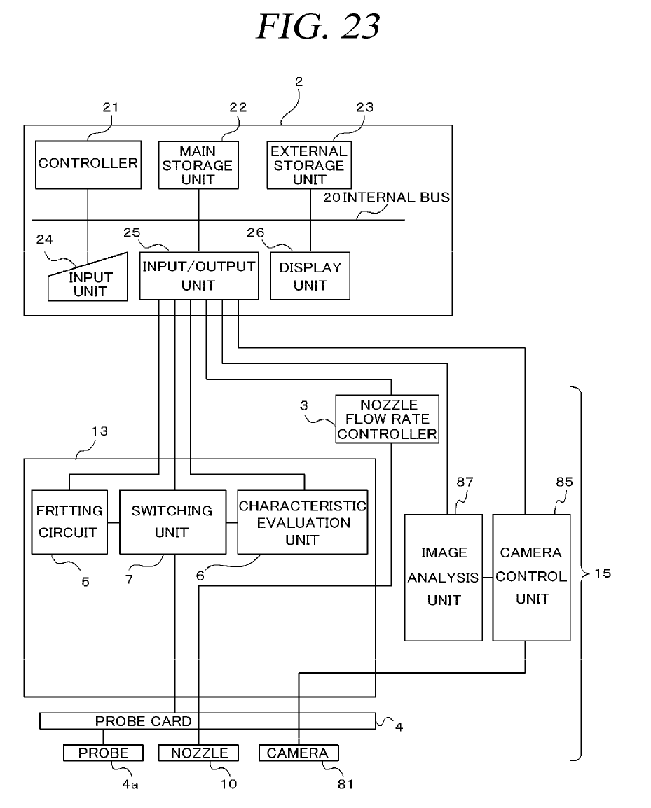

FIG. 23 is a block diagram showing the inspection control unit 2 and a prober unit 15 of the inspecting apparatus 1 in accordance with the present modification example. Though positions of some functional blocks are slightly moved for the reason of illustration, the basic configuration of FIG. 23 is identical to that of FIG. 2 excepting that the camera 81, the camera control unit 85 and the image analysis unit 87 are added.

The camera control unit 85 is directly connected with the camera 81, and carries out a position alignment of the camera 81, a transmission of a photographing instruction, a capture of image, and so forth. The image analysis unit 87 carries out an image analysis for detecting the foreign substances based on the image obtained by the camera control unit 85 from the camera 81. The cameral control unit 85 and the image analysis unit 87 carry out a transception of data or commands with respect to an input/output unit 25 in the inspection control unit 2.

Further, though the image analysis unit 87 is shown to be located outside the inspection control unit 2 in FIG. 23, it is also possible to store the image analysis unit 87 as a program in an external storage unit 23 in the inspection control unit 2. In such case, as the program is read out by the controller 21 when necessary, it can serve as the image analysis unit 87.

Moreover, it is to be noted that the above-described hardware configurations or the flowcharts are nothing more than examples, so that they can be changed or modified in various ways. Further, besides the air, a gas necessary for the internal atmosphere of the inspection apparatus 1, for example, nitrogen can be used as the gas discharged from or sucked into the nozzles 10.

The inspection control unit 2 of the inspecting apparatus 1 can be implemented not only by a dedicated system but also by a typical computer system. For example, it may be possible to constitute the inspection control unit 2 for performing the above-described process by storing a computer program for performing the above-described operation in a computer-readable storage medium (a flexible disk, a CD-ROM, a DVD-ROM, or the like), distributing the computer program and installing the computer program on a computer. Alternatively, it may be also possible to constitute the inspection control unit 2 by storing the computer program in a storage device of a server on communication networks such as the Internet, and then downloading the computer program by a typical computer system.

Moreover, when each of the above-described functions is implemented by a division of operation between an operating system (OS) and an application program or by a cooperation of the OS and the application program, it may be possible to store only the application program in a storage medium or a storage device.

In addition, the computer program can be distributed as a data signal embodied in a carrier wave over communication networks.

It is clear that the above-described embodiments are illustrative in all aspects and do not limit the present invention. The scope of the present invention is defined by the following claims rather than by the detailed description of the embodiment, and it shall be understood that all modifications and embodiments conceived from the meaning and scope of the claims and their equivalents are included in the scope of the present invention.

The present application claims the benefit of Japanese Patent Application Ser. No. 2006-122160, filed on Apr. 26, 2006, of which specification, claims and drawings are hereby incorporated by reference in its entirety.

### INDUSTRIAL APPLICABILITY

A flow of a gas can be precisely controlled by using a plurality of nozzles, and a movable section of a microstructure can be freely displaced by the flow of the gas. Therefore, the present invention can be applied to inspecting microstructures under various manufacturing processes.

What is claimed is:

1. A microstructure inspecting apparatus for evaluating a characteristic of at least one microstructure having a movable section formed on a substrate, comprising:
a probe, which electrically connects with an inspection electrode formed on the microstructure, for obtaining an electric signal of the microstructure;
a plurality of nozzles, positioned in the vicinity of the movable section of the microstructure, for discharging or sucking a gas;
a gas flow rate control unit for controlling a flow rate of the gas discharged from or sucked into the plurality of nozzles; and
an evaluation unit for detecting a displacement of the movable section of the microstructure by using the electric signal obtained through the probe, wherein the displacement is made by the gas discharged from or sucked into the plurality of nozzles, and evaluating the characteristic of the microstructure based on the detected result.

2. The microstructure inspecting apparatus of claim 1, further comprising:
a probe card, connected to the evaluation unit, including the probe and the plurality of nozzles.

3. The microstructure inspecting apparatus of claim 1, further comprising:
at least one sound wave generating unit for outputting a test sound wave to the movable section of the microstructure.

4. The microstructure inspecting apparatus of claim 1, further comprising:
a conducting unit for electrically connecting the probe with the inspection electrode by using a fritting phenomenon.

5. The microstructure inspecting apparatus of claim 1, wherein the gas flow rate control unit removes foreign substances adhered to the microstructure by controlling the flow rate of the gas discharged from or sucked into the plurality of nozzles.

6. The microstructure inspecting apparatus of claim 2, wherein the probe card further includes a foreign substance detecting unit for detecting foreign substances adhered to the microstructure, and
if the foreign substances are detected by the foreign substance detecting unit, the gas flow rate control unit removes the foreign substances adhered to the microstructure by controlling the flow rate of the gas discharged from or sucked into the plurality of nozzles.

7. The microstructure inspecting apparatus of claim 6, wherein the foreign substance detecting unit determines presence and location of the foreign substances by means of an image analyzing unit.

8. The microstructure inspecting apparatus of claim 1, wherein the microstructure is an acceleration sensor formed on the substrate.

9. The microstructure inspecting apparatus of claim 1, wherein the microstructure is a device formed on a semiconductor wafer.

10. A microstructure inspecting method comprising:
in order to obtain an electric signal of at least one microstructure having a movable section formed on a substrate, contacting a probe with a pad formed on the microstructure;
positioning nozzles for discharging or sucking a gas in the vicinity of the movable section of the microstructure, to displace the movable section of the microstructure;
displacing the movable section of the microstructure by discharging or sucking the gas from the nozzles;
detecting a displacement of the movable section of the microstructure by using the electric signal obtained through the probe, wherein the displacement is made by the gas discharged from or sucked into the nozzles; and
evaluating a characteristic of the microstructure based on the displacement of the movable section detected by the electric signal.
